(19) United States
(12) Patent Application Publication
(10) Pub. No.: US 2020/0116755 A1
(43) Pub. Date: Apr. 16, 2020

(54) TEST INTERFACE SYSTEM AND METHOD OF MANUFACTURE THEREOF

(71) Applicant: AIS Technology, Inc., Pleasanton, CA (US)

(72) Inventor: Raymond W. Bae, Danville, CA (US)

(21) Appl. No.: 16/160,344

(22) Filed: Oct. 15, 2018

(51) Int. Cl. G01R 1/04; G01R 3/00; G01R 31/28; G01R 1/073; G01R 1/067

(52) U.S. Cl. CPC G01R 1/0416; G01R 3/00; G01R 1/06761; G01R 1/07378; G01R 31/2831

(57) ABSTRACT

A redistribution system includes: a probe support base; a homogenous dielectric structure formed on the probe support base; a probe head structure formed on the homogenous dielectric structure, including: a probe conductive connector partially embedded in and extending from the homogenous dielectric structure; a probe head support adjacent to the probe conductive connector and extending from the homogenous dielectric structure; and a deflectable probe head attached to the probe conductive connector and suspended over a deflection gap between the probe conductive connector probe head support.

### TECHNICAL FIELD

An embodiment of the present invention relates generally to a redistribution system, and more particularly to a test interface system with a probe head structure.

### BACKGROUND

Modern consumer and industrial electronics, cellular phones, mobile devices, and computing systems, are providing increasing levels of functionality to support modern life including. Research and development in the existing technologies can take a myriad of different directions.

As users become more empowered with the growth of computing devices, new and old paradigms begin to take advantage of this new device space. There are many technological solutions to take advantage of this new device capability and device miniaturization. However, as devices continue to decrease in size while increasing functionality, reliable testing of wafers through new devices has become a concern for manufactures.

Thus, a need still remains for a test interface system for testing of wafers through devices. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a test interface system, including: a probe support base; a homogenous dielectric structure formed on the probe support base; a probe head structure formed on the homogenous dielectric structure, including: a probe conductive connector partially embedded in and extending from the homogenous dielectric structure; a probe head support adjacent to the probe conductive connector and extending from the homogenous dielectric structure; and a deflectable probe head attached to the probe conductive connector and suspended over a deflection gap between the probe conductive connector probe head support.

An embodiment of the present invention provides a method of manufacture of a test interface system including: providing a probe base; forming a portion of a probe conductive connector on the probe base; forming a homogenous dielectric structure around the portion of the probe conductive connector; forming a probe head structure on the homogenous dielectric structure including: forming a subsequent portion of the probe conductive connector extending away from the homogenous dielectric structure; forming a probe head support adjacent to the probe conductive structure and extending from the homogenous dielectric structure; and forming a deflectable probe head attached to the probe conductive connector and suspended over a deflection gap between the probe conductive connector probe head support.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a schematic side view of a test interface system in an embodiment of the present invention.

FIG. 2 is a top view of the test interface platform in a first embodiment of the test interface system.

FIG. 3 is a cross-sectional view of the test interface platform of FIG. 2 along line 3--3 of FIG. 2.

FIG. 4 is a cross sectional view of the probe support base in forming a portion of the probe conductive connectors of FIG. 3.

FIG. 5 is the structure of FIG. 4 in forming the homogenous dielectric structure of FIG. 3.

FIG. 6 is the structure of FIG. 5 in forming the probe support structure and the probe conductive connectors.

FIG. 7 is the structure of FIG. 6 in forming the deflectable probe head of FIG. 3.

FIG. 8 is the structure of FIG. 7 in forming the test interface platform.

FIG. 9 is a cross sectional view of the test interface platform of FIG. 2 along line 9--9 of FIG. 3 in a second embodiment of the test interface system.

FIG. 10 is a top view of the test interface platform in a third embodiment of the test interface system.

FIG. 11 is a cross sectional view of the test interface platform of FIG. 10 along line 11--11 of FIG. 10.

FIG. 12 is a top view of the test interface platform in a fourth embodiment of the test interface system.

FIG. 13 is a cross sectional view of the test interface platform of FIG. 12 along line 13--13 of FIG. 12.

FIG. 14 is a cross sectional view of the test interface platform of FIG. 12 along line 14--14 of FIG. 12 in a fifth embodiment of the test interface system.

FIG. 15A-15D, therein are shown top views of the probe head structure of FIG. 1.

FIG. 16 is a flow chart of a method of manufacturing of a test interface system in an embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The designation and usage of the term first, second, third, etc. is for convenience and clarity and is not meant limit a particular order. The steps or processes described can be performed in any order to implement the claimed subject matter.

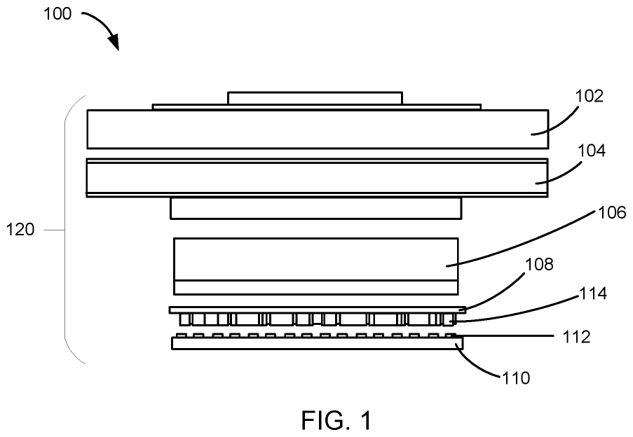

Referring now to FIG. 1, therein is shown a schematic side view of a test interface system 100 in an embodiment of the present invention. The test interface system 100 is a system for providing interconnection between different devices. For example, the test interface system 100 can be a component in a wafer testing system 120. As an example, the wafer testing system 120 can include a mechanical stiffener 102, a printed circuit board 104, a redistribution platform 106, and a test interface platform 108. The mechanical stiffener 102, the printed circuit board 104, the redistribution platform 106, and the test interface platform 108 are components for a system to test a device under test 110. The device under test 110 can be a processed silicon wafer with electronic components (not shown), such as circuits, integrated circuits, logic, integrated logic, or a combination thereof fabricated thereon.

The test interface platform 108 is an interface for contacting test locations on the device under test 110, which can include semiconductor dice 112 fabricated thereon. The test interface platform 108 can include probe head structures 114. The probe head structures 114 are the structures that contact the device under test 110. For example, the probe head structures 114 can be for contacting testing points or chip connecting pads (not shown) on the components formed on the surface of the device under test 110, such as the semiconductor dice 112 or microelectromechanical system.

The redistribution platform 106 is structure for providing interconnection between two devices. For example, the redistribution platform 106 can be a space transformer. For illustrative purposes, the redistribution platform 106 is shown as a component that can provide electrical connectivity between the test interface platform 108 and the printed circuit board 104 of the wafer testing system 120. The redistribution platform 106 can provide electrical and functional connectivity between the device under test 110, semiconductor dice 112, or a combination thereof for system testing, such as wafer testing, die testing, package testing, or inter-package testing.

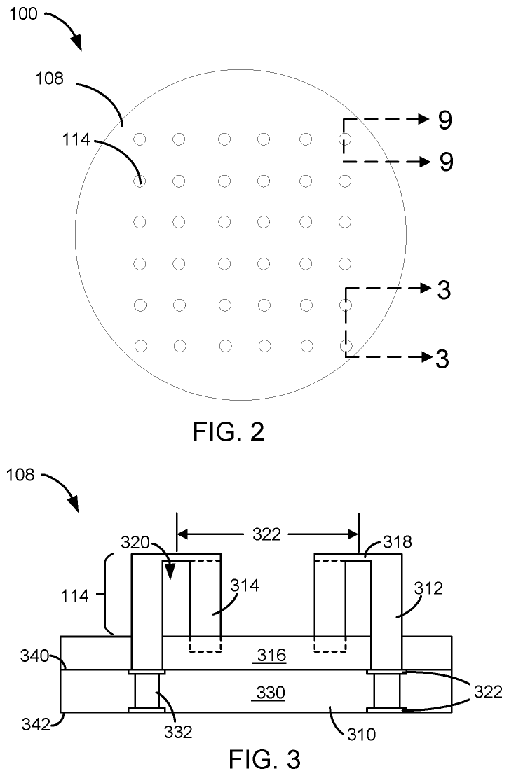

Referring now to FIG. 2, therein is shown a top view of the test interface platform 108 in a first embodiment of the test interface system 100. For illustrative purpose, test interface platform 108 is depicted having a circular shape, although it is understood that the test interface platform 108 can have a different shape. For example, the test interface platform 108 can have a shape to meet the needs of the testing equipment or setup, such as a square or rectangular shape, a triangular shape, pentagonal shape, or any other polygonal shape.

The test interface platform 108 is shown including the probe head structure 114. For illustrative purposes, the surface of the probe head structure 114 is shown having a circular or elliptical shape, although it is understood that the probe head structure 114 can have a different shape. For example, the probe head structure 114 can have a square or rectangular shape, a triangular shape, pentagonal shape, or any other polygonal shape. The number, pattern, location, pitch, diameter, and size of the probe head structure 114 are shown for illustrative purposes and are not drawn to scale.

Referring now to FIG. 3, therein is shown a cross-sectional view of the test interface platform 108 of FIG. 2 along line 3--3 of FIG. 2. The test interface platform 108 can include a probe support base 310. The probe support base 310 is a structure that provides structural rigidity for the test interface platform 108.

In this implementation, the probe support base 310 is a substrate 330. The substrate 330 can be a rigid foundation or base layer for the test interface platform 108. As an example, the substrate 330 can be provided as an electrically insulating material. As a specific example, the substrate 330 can be a ceramic based material, such as a high temperature co-fired ceramic (HTCC) or a low temperature co-fired ceramic (LTCC). As another specific example, the substrate 330 can be a polymer composite based material, such as a fiber reinforced polymer. As a specific example, the polymer based composite can include fiberglass reinforced epoxy laminates, such as Flame Retardant-4 (FR-4) grade printed circuit boards.

The substrate 330 can include a substrate first side 340 and a substrate second side 342. The substrate first side 340 and the substrate second side 342 can be the opposing surfaces of the substrate 330 that face away from one another. The substrate first side 340 and the substrate second side 342 can be substantially parallel with one another.

The substrate 330 can include through substrate vias 332. The through substrate vias 332 are structures that extends from one surface of the substrate 330 to an opposing surface of the substrate 330. For example, the through substrate vias 332 can extend between the substrate first side 340 and the substrate second side 342. As an example, the through substrate vias 332 can be formed from electrically conductive material, including metals, such as elemental copper, silver, or gold, or metallic alloys, such as copper alloys, silver alloys, or gold alloys. For illustrative purposes, the through substrate vias 332 are shown connected to contact pads 334, however, it is understood that the contact pads 334 are optional and the through substrate vias 332 can exposed directly at the substrate first side 340, the substrate second side 342, or a combination thereof. Optionally, the portion of the through substrate vias 332 exposed at the substrate first side 340, the substrate second side 342, or a combination thereof, can be co-planar with the substrate first side 340 or the substrate second side 342, respectively.

For illustrative purposes, the probe support base 310 is shown as the substrate 330, however it is understood that the probe support base 310 can be different structures in different implementation or embodiments. For example, in another implementation, the probe support base 310 can be the redistribution platform 106 of FIG. 1. In a further implementation, the probe support base 310 can be the device under test 110 of FIG. 1.

The test interface platform 108 can include a homogenous dielectric structure 316 formed on the probe support base 310. The homogenous dielectric structure 316 is a uniform structure formed from a single material. For example, the homogenous dielectric structure 316 can be a structure formed from a polymer material. The homogenous dielectric structure 316 can be a homogenous polymer structure that does not include any interstitial material, such as fiber or particle reinforcement. The lack of interstitial or embedded material enables the homogenous dielectric structure 316 to be translucent or transparent according to the properties of the dielectric material used to form the homogenous dielectric structure 316. Since the homogenous dielectric structure 316 is formed of a single material, the homogenous dielectric structure 316 can have uniform structural and thermal properties, such as a uniform coefficient of thermal expansion.

The homogenous dielectric structure 316 can be transparent or translucent. Transparent or translucent refers to allowing light in the visible wavelength spectrum to pass through. As an example, an object can be visually seen, at least partially, through a translucent material. As another example, an object can be seen, potentially distinctly, through a transparent material.

The homogenous dielectric structure 316 can include probe conductive connectors 312 embedded therein. The probe conductive connectors 312 can be used to transmit electrical signals throughout the test interface platform 108. For example, in one embodiment, the probe conductive connectors 312 can facilitate the transmission of electrical signals from the probe head structure 114 to the redistribution platform 106 of FIG. 1 through the probe support base 310. The probe conductive connectors 312 can be partially embedded in homogenous dielectric structure 316 and can extend through the homogenous dielectric structure 316 to the probe support base 310. The homogenous dielectric structure 316 can provide electric insulation between each of the probe conductive connectors 312 embedded in the homogenous dielectric structure 316. A portion of the probe conductive connectors 312 can be exposed from and extend away from the homogenous dielectric structure 316.

The probe head structure 114 can include the exposed portion of the probe conductive connectors 312, a deflectable probe head 318, and a probe head support 314. The deflectable probe head 318 is the surface which provides the point of contact with the testing points, such as the testing points on the device under test 110. The deflectable probe head 318 can be made of conductive material including metals, such as elemental copper, silver, or gold, or metallic alloys, such as copper alloys, silver alloys, or gold alloys. In general, the probe head support 314 is made from a material that is the same as or similar to the probe conductive connectors 312.

The probe head support 314 is a structure to support the deflectable probe head 318. The probe head support 314 can contact the homogenous dielectric structure 316 at one end and be attached to the deflectable probe head 318 at an opposing end that extends away from homogenous dielectric structure 316. In some implementations, the probe head support 314 can contact but not be attached or bonded with the deflectable probe head 318 as indicated by the dashed line. In other implementations, the probe head support 314 can be attached to the deflectable probe head 318, such as through metallic or chemical bonding. Each of the subsequent FIGs. Indicate the possible non-attached contact or direct attachment between the probe head support 314 and the deflectable probe head 318 by the dashed line.

The probe head support 314 can be made of a number of different materials. For example, the probe head support 314 can be made from a conducive material including metals, such as elemental copper, silver, or gold, or metallic alloys, such as copper alloys, silver alloys, or gold alloys. In another example, the probe head support 314 can be made from a dielectric material, such as a polymer material. In a further example, the probe head support 314 can be made of a material that is the same as or similar to that of the probe conductive connector 312, the deflectable probe head 318, or a combination thereof

The probe head support 314 is shown FIG. 3 and subsequent FIGs. as attached at the surface of the homogenous dielectric structure 316, although it is understood that the probe head support 314 can be embedded in the homogenous dielectric structure 316, as indicated by the dashed lines. Further, the probe head support 314 can extend partially through the homogenous dielectric structure 316 or fully extend through the homogenous dielectric structure 316 to the surface of the probe support base 310.

Each of the probe conductive connectors 312 can be paired with one or more of the probe head support 314 to suspend the deflectable probe head 318 over the homogenous dielectric structure 316. The probe head support 314 and the corresponding instance of the probe conductive connectors 312 can provide semi-rigid support for the deflectable probe head 318. Semi-rigid support refers to the ability of a material to undergo elastic deformation.

The probe head support 314 can be spaced apart from the corresponding instance of the probe conductive connectors 312 to include a deflection gap 320 under the deflectable probe head 318 and between the homogenous dielectric structure 316 and the deflectable probe head 318. As an example the probe conductive connectors 312 and the probe head support 314 can be attached at opposite ends of the deflectable probe head 318. As a specific example, the deflection gap 320 between the probe conductive connectors 312 and the probe head support 314 can be 5 to 10 microns. In general, the deflection gap 320 can span through the entire probe head structure 114 between the probe conductive connector 312 and the probe head support 314 to form an open arch structure with the deflectable probe head 318. However, it is understood that the deflection gap 320 can be partially of fully obstructed at one or both ends of the probe head structure 114 by the probe conductive connector 312, the probe head support 314, or a combination thereof to enclose or partially enclose the deflection gap 320. For illustrative, the probe head support 314 and the probe conductive connector 312 are shown connected at the edges of the deflectable probe head 318, although it is understood that the probe head support 314, the probe conductive connector 312, or a combination thereof can be attached to the deflectable probe head 318 at a different position. For example, the probe head support 314, the probe conductive connector 312, or a combination thereof can be offset from the edge of the deflectable probe head 318 such that the deflectable probe head 318 overhangs the probe head support 314, the probe conductive connector 312, or a combination thereof

In this embodiment, the deflectable probe head 318 can be a sheet of conductive material. The thickness of the deflectable probe head 318 and position of the deflectable probe head 318 over the deflection gap 320 can enable the deflectable probe head 318, the probe conductive connectors 312, the probe head support 314 or a combination thereof to undergo elastic deformation, which allows the probe head structure 114 to flex under load and return to its original shape once the load has been removed, such as during repetitive contact with the device under test 110 of FIG. 1.

It has been discovered that ability of the deflectable probe head 318, the probe conductive connectors 312, the probe head support 314 or a combination thereof to undergo elastic deformation during contact with the device under test 110 extends the life of the test interface platform 108. The flexing of the deflectable probe head 318, the probe conductive connectors 312, the probe head support 314 or a combination thereof can spread the load across each of the elements, reducing the cyclic fatigue on any one of the elements in the probe head structure 114, thus extending the lifespan of the test interface platform 108.

It has also been discovered that surface area of the deflectable probe head 318 in the sheet configuration improves testing reliability. Relative to conventional probe structures, such as probe pins, the sheet configuration of the deflectable probe head 318 provides a greater surface area to contact interconnect structures (not shown) on the device under test 110, such as microbumps, formed on the contact pads (not shown) of the device under test 110. In the case of probe pins, a misaligned contact between the device under test 110 interconnect structures can result in non-contact, damage, or dislodging of the interconnect structures. Due to the greater contact surface area of the sheet configuration, the deflectable probe head 318 will have an increased likelihood of deflectable probe head 318 to contact the test points and prevent damage to the contact interconnect structures.

The probe head structures 114 can include a pitch 322. The pitch 322 refers to the shortest measure between the center to center distances between features, such as between adjacent instances of the probe head structures 114. In general, the pitch 322 between the probe head structures 114 is less than 20 microns. In general, the probe conductive connectors 312 can have a width that is less than that of the probe head structures 114. For example, the probe conductive connectors 312 can have a width of less than 10 microns. In another example, the probe conductive connectors 312 can have a width of less than 5 microns. Similarly, the probe head support 314 can have a width that is less than that of the probe head structures 314. For example, the probe head support 314 can have a width of less than 10 microns. In another example, the probe head support 314 can have a width of less than 5 microns. The deflectable probe head 318 can have a thickness that is of varying widths. For example, the thickness of the deflectable probe head 318 can be less than 10 microns. In a more specific example, the deflectable probe head 318 can have a thickness that is less than 5 microns.

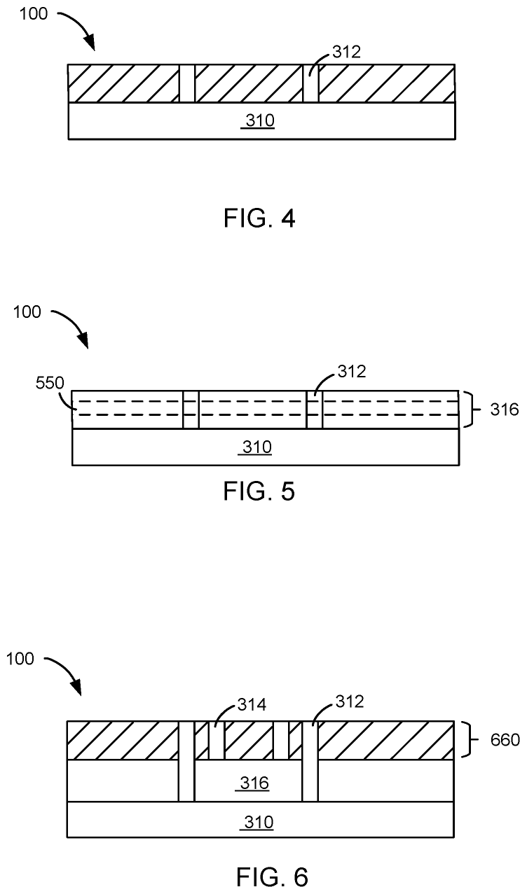

Referring now to FIG. 4, therein is shown a cross sectional view of the probe support base 310 in forming a portion of the probe conductive connectors 312 of FIG. 3. The probe conductive connectors 312 can be formed through a connector formation process, which can be a multi-phase process to pattern and form the portions of the probe conductive connectors 312. For example, the connector formation process can include a masking phase, an etching phase, a seeding phase, a deposition phase, a planarization phase, a mask removal phase, or a combination thereof. As an example, the portion of the probe conductive connectors 312 is shown following the masking phase, the seeding phase, the deposition phase, and the planarization phase, but prior to removal of a shaping structure in the mask removal phase.

The portion of the probe conductive connectors 312 can be formed by a number of different processes. For example, the probe conductive connectors 312 can be formed by processes including electrolytic deposition, diffusion, lithography, chemical mechanical planarization, or a combination thereof. As a specific example, the probe conductive connectors 312 can be formed by an electrolytic deposition process resulting in a uniform morphology between subsequent portions of the probe conductive connectors 312.

In general, the probe conductive connectors 312 can be formed as a column or pillar perpendicular to and extending away from the surface of the probe head support 314. The probe conductive connectors 312 can be formed from conductive material that can include metals, such as elemental copper, silver, or gold, or metallic alloys, such as copper alloys, silver alloys, or gold alloys.

In one implementation, the probe support base 310 can be provided as the substrate 330 of FIG. 3. In another implementation, the probe support base 310 can be provided as the redistribution platform 106 of FIG. 1. In a further implementation, the probe support base 310 can be provided as the device under test 110 of FIG. 1 including a post-passivation structure formed thereon.

Referring now to FIG. 5, therein is shown the structure of FIG. 4 in forming the homogenous dielectric structure 316 of FIG. 3. The homogenous dielectric structure 316 can be formed from one or more polymer layers 550. The polymer layers 550 are layers of a polymer material formed to cover the probe conductive connectors 312, the probe support base 310, or a combination thereof The polymer layers 550 can be an electrically insulating material, which can cover portions of and electrically insulate each instance of the probe conductive connectors 312 from one another.

In general, each of the polymer layers 550 can be formed through a polymer buildup process. As an example, the polymer buildup process can include an application phase and a curing phase. In the application phase of the polymer buildup process, all or a portion of the probe conductive connectors 312, the probe support base 310, or a combination thereof can be covered by an application of a liquid dielectric precursor material (not shown).

The liquid dielectric precursor material can be an organic solution or organic suspension. For example, the liquid dielectric material can be a solution of monomer or oligomer molecules for a polymer, suspended or dissolved in a solvent. The liquid dielectric precursor material can be a solution that includes monomer or oligomer molecules as a precursor for one of a variety of different polymer materials. For example, the liquid dielectric precursor material can be a precursor for polyimide based polymers, epoxy based polymer, or other types of polymers. As a specific example, the liquid dielectric precursor material can include monomer or oligomer molecules that are capable of polymerization through a condensation reaction. In a further specific example, the liquid dielectric precursor material can include cross-linking or end-cap monomer units, which can be involved in cross-linking in a subsequent curing phase.

The end-cap monomer units are molecules that can stop or end the polymerization reaction of a particular molecule. More specifically, once each end of the a linear polymer molecule, or a polymer molecule that does not include branching into multiple polymer chains, has reacted with one of the end-cap monomer molecules, the polymer molecule can no longer react with the other non-end-cap monomer or oligomer molecules. In other words, once each end of the polymer molecule has reacted with an end-cap molecule, the polymer molecule can no longer increase in molecular weight outside of a cross-linking reaction, which will be discussed in detail below.

The liquid dielectric precursor material can be applied in a number of ways. For example, the liquid dielectric precursor material can be applied through a spin-coating process to cover the portions of the probe conductive connectors 312, the probe support base 310, or a combination thereof. As another example, the liquid dielectric precursor material can be applied through a method that can provide uniform distribution and thickness of the liquid dielectric precursor material across the probe support base 310.

Following the application phase, the polymer buildup process can proceed to the curing phase. In the curing phase, of the liquid dielectric precursor material can be heated to form an instance of the polymer layers 550. In general, the liquid dielectric precursor material can be heated to a polymerization temperature for a time period that promotes polymer molecule chain building from the monomer or oligomer molecules. However, the polymerization temperature is different from a cross-linking temperature, which is a temperature at which cross-linking between the end-cap or cross-linking monomer molecules occurs. More specifically, the polymerization temperature can be a lower temperature than the temperature for cross-linking of an end-cap or cross-linking monomer molecules. The polymer molecules of the polymer layers 550 can be formed with a length or molecular weight that is statistically proportional to the number of monomer units and the end-cap units in the liquid dielectric precursor material.

Optionally, the curing phase can include a volatile removal or degassing phase to remove volatile components in the liquid dielectric precursor material. As an example, the volatile components can include evaporating solvent molecules or molecules formed during the polymerization of the liquid dielectric precursor material. The optional volatile removal phase can include a gradual temperature increase to or temperature hold near the boiling point of the solvent of the liquid dielectric precursor material. The optional volatile removal phase can include agitation of the liquid dielectric precursor material through vibration, such as ultrasonic vibration, during to facilitate removal of volatile components. The volatile removal phase can prevent void formation due to gasses trapped in the polymer layers 550 and at the interface between the probe conductive connectors 312 and the polymer layers 550.

Each of the polymer layers 550 can include a polymer layer thickness. The polymer layer thickness for each of the polymer layers 550 can be determined after the curing phase. As an example, since the polymer layers 550 are transparent, optical thickness measurement methods can be employed to determine the polymer layer thickness for each of the polymer layers 550. Each of the polymer layers 550 can have a different value for the polymer layer thickness. For example, the polymer layer thickness for each of the polymer layers 550 can be in a range of 1 micrometer to 20 micrometers. As a specific example, the polymer layer thickness for each of the polymer layers 550 can be in a range of 1 micrometer to 5 micrometers.

The polymer layers 550 can be formed sequentially through iterative implementation of the polymer buildup process. With the exception of the instance of the polymer layers 550 formed on the probe support base 310, each of the polymer layers 550 can be formed directly on the previously formed instance of the polymer layers 550 until the probe conductive connectors 312 are completely covered.

For illustrative purposes, the structure of FIG. 5 is shown with 3 instances of the polymer layers 550 formed to cover the probe conductive connectors 312, as indicated by the dashed lines. However, it is understood that a different number of the polymer layers 550 can be formed to cover the probe conductive connectors 312. For example, the probe conductive connectors 312 can be covered by a single instance of the polymer layers 550.

In another implementation the polymer buildup process can applied in combination with the connector formation process of FIG. 4 to form the probe conductive connectors 312. For example, the connector formation process and the polymer buildup process can be successively applied to form the embedded portion of the probe conductive connectors 312.

Following the polymer buildup process, the plurality of the polymer layers 550 can be further processed to form the homogenous dielectric structure 316. The homogenous dielectric structure 316 can be a structure that does not include any interstitial material, such as fiber or particle reinforcement. The absence or lack of interstitial or embedded reinforcement material enables the homogenous dielectric structure 316 to be translucent or transparent according to the properties of the dielectric material used to form the homogenous dielectric structure 316.

The homogenous dielectric structure 316 can be formed through cross-linking between the polymer layers 550. More specifically, the homogenous dielectric structure 316 can be formed by heating the polymer layers 550 to a cross-linking temperature, or a temperature that facilitates or promotes the formation of chemical bonds between the end-caps throughout the polymer layers 550 and at the interface between adjacent instances of the polymer layers 550 to form a single continuous structure. The crosslinking temperature can be different from the temperature to form the polymer molecules of the polymer layers 550. In general, the cross-linking temperature is higher than that of the temperature for polymerization of the liquid dielectric precursor material. The cross-linking temperature can vary based on the end-cap unit used for forming the cross-linking bonds between the polymer molecules.

It has been discovered that the homogenous dielectric structure 316 formed by cross-linking of polymer molecules between the polymer layers 550 eliminates the need for an intervening bonding material or adhesive.

The surface of the homogenous dielectric structure 316 facing away from the probe support base 310 can be planarized to be co-planar with the portions of the probe conductive connectors 312. The portions of the homogenous dielectric structure 316 and the probe conducive connectors 312 can be removed by a number of different processes. For example, the removal process can include chemical polishing, chemical grinding, mechanical polishing, mechanical grinding, or a combination thereof

Referring now to FIG. 6, therein is shown the structure of FIG. 5 in forming the probe head support 314 and the probe conductive connectors 312. The portion of the probe conductive connector 312 extending beyond the homogenous dielectric structure 316, referred to as the subsequent portion, can be formed in a stacked configuration through a subsequent application of the connector formation process of FIG. 4, which can include the masking phase, the etching phase, the seeding phase, the deposition phase, the planarization phase, a mask removal phase, or a combination thereof. During the masking phase, an extension shaping structure 660 can be formed on homogenous dielectric structure 316 to form the subsequent portion of the probe conducive connectors 312. During the etching phase, the extension shaping structure 660 can be etched to expose the embedded portion of the probe conductive connectors 312.

The probe conductive connectors 312 can be formed in the stacked configuration by forming subsequent portion of the probe conductive connectors 312 directly on and aligned with the portion of the probe conductive connectors 312 embedded in the homogenous dielectric structure 316, referred to as the embedded portion. As an example, the probe conductive connectors 312 can be formed by processes including electrolytic deposition, diffusion, lithography, chemical mechanical planarization, or a combination thereof. As a specific example, the probe conductive connectors 312 can be formed by an electrolytic deposition process resulting in a uniform morphology between subsequent portions of the probe conductive connectors 312. In general, the subsequent portion of the probe conductive connectors 312 are formed of the same material and having the same cross-sectional dimensions as those of the probe conductive connectors 312 embedded in the homogenous dielectric structure 316.

It has been discovered that using the same conductive material to form the embedded portion and the subsequent portion of the probe conductive connectors 312 in the stacked configuration using the techniques described above allows the formation of larger uniform structures. This uniform structure provides improved structural integrity as opposed to those using different conductive materials to form the embedded portion and the subsequent portion of the probe conductive connectors 312. In this example, the direct stack approach allows the materials for the probe conductive connectors 312 or the portions of the probe conductive connectors 312 themselves to be formed directly to another portions of the probe conductive connectors 312 with no intervening elements or structures. Examples of intervening elements include different materials, such as tungsten, palladium, aluminum, when the probe conductive connectors 312 is formed from copper or copper alloy. Example of intervening structures include landing pads from the probe conductive connectors 312 to a separate via (not shown) formed for a different material. Instead, structural and electrical connectivity between portions of the probe conductive connectors 312 can be formed by directly stacking the additional portions of the probe conductive connectors 312 with the process used to form the embedded or previous portions of the probe conductive connectors 312.

It has been further discovered that using the same conductive material to form the portions of the probe conductive connectors 312 results in greater signal integrity throughout the test interface system 100. The probe conductive connectors 312 formed from a single material reduces signal reflection at junctures where the probe conductive connectors 312 are attached or fused to other portions of the probe conductive connectors 312 due to the uniform morphology between subsequent or preceding portions of the probe conductive connectors 312, which improves signal integrity.

It has yet further been discovered that forming the probe conductive connectors 312 in the stacked configuration through the connector formation process can achieve the pitch between the probe head structure 114 on a scale of less than or equal to 20 microns.

The probe head support 314 can be formed by a process similar to the connector formation process. For example, the head support formation process can include a masking phase, an etching phase, a seeding phase, a deposition phase, a planarization phase, a mask removal phase, or a combination thereof The extension shaping structure 660 can be used or modified to form the probe head support 314. In one implementation, the probe head support 314 can be formed to be partially embedded in a portion of the homogenous dielectric structure 316. In another implementation, the probe head support 314 can be formed to be attached at the surface of the homogenous dielectric structure 316.

In general, for the formation of the probe head structure 114, the extension shaping structure 660 is planarized with the probe head support 314 and the probe conductive connectors 312. More specifically, the surface of the extension shaping structure 660, the probe head support 314, and the probe conductive connectors 312 facing away from the probe support base 310 can be processed to be co-planar. As an example, the extension shaping structure 660, the probe head support 314, and the probe conductive connectors 312 can be planarized by a removal process, such as chemical polishing, chemical grinding, mechanical polishing, mechanical grinding, or a combination thereof. The extension shaping structure 660 can be left intact to facilitate or enable formation of the deflectable probe head 318.

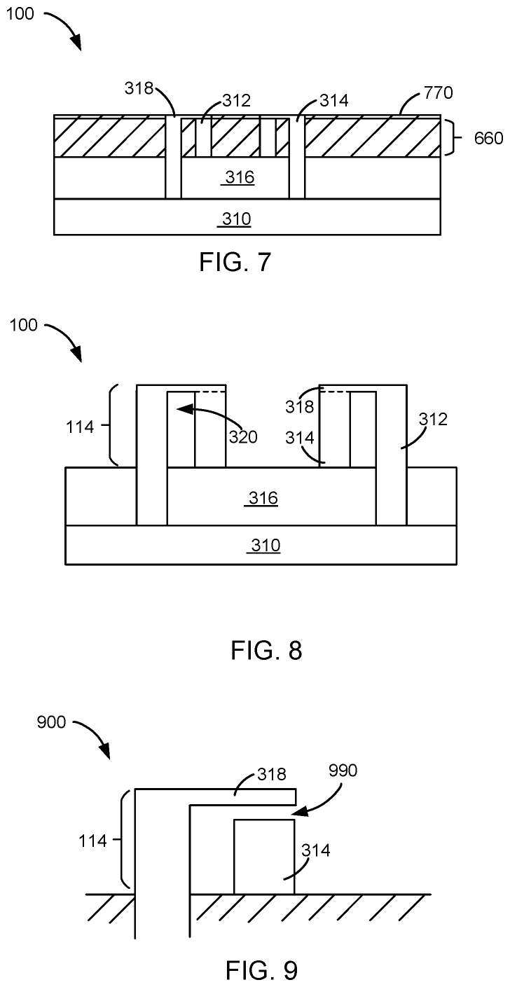

Referring now to FIG. 7, therein is shown the structure of FIG. 6 in forming the deflectable probe head 318 of FIG. 3. The deflectable probe head 318 can be formed in a further application of the connector formation process of FIG. 4, which can include the masking phase, the etching phase, the seeding phase, the deposition phase, the planarization phase, a mask removal phase, or a combination thereof. During the masking phase, a probe head shaping structure 770 can be formed on the extension shaping structure 660, the probe head support 314, the probe conductive connectors 312 or a combination thereof to form the deflectable probe head 318. During the etching phase, the probe head shaping structure 770 can be etched to expose the probe head support 314 the probe conductive connectors 312 or a combination thereof.

The deflectable probe head 318 can be can be formed by a number of different processes. For example, the deflectable probe head 318 can be formed by processes including electrolytic deposition, diffusion, lithography, chemical mechanical planarization, or a combination thereof. As a specific example, the probe conductive connectors 312 can be formed by an electrolytic deposition process resulting in a uniform morphology between the deflectable probe head 318 and the probe conductive connectors 312. In general, the subsequent portion of the deflectable probe head 318 and the probe conductive connectors 312 are formed of the same material. In this implementation, the deflectable probe head 318 can be formed as a sheet, however it is understood that the deflectable probe head 318 can be formed having different shapes.

During the planarization phase, the surface of the probe head shaping structure 770 and the deflectable probe head 318 facing away from the probe support base 310 can be processed to be co-planar. As an example, the probe head shaping structure 770 and the deflectable probe head 318 can be planarized by a removal process, such as chemical polishing, chemical grinding, mechanical polishing, mechanical grinding, or a combination thereof. The extension shaping structure 660 can be left intact to facilitate or enable formation of the deflectable

Referring now to FIG. 8, therein is shown the structure of FIG. 7 in forming the test interface platform 108. The extension shaping structure 660 of FIG. 6 and the probe head shaping structure 770 of FIG. 7 can be removed to produce the probe head structure 114, including the portion of the probe conductive connectors 312 exposed from the homogenous dielectric structure 316, the probe head support 314, and the deflectable probe head 318. Removing the extension shaping structure 660 and the probe head shaping structure 770 creates the deflection gap 320 and suspends the deflectable probe head 318 over the deflection gap 320.

Referring now to FIG. 9, therein is shown a cross sectional view of the test interface platform 108 of FIG. 2 along line 9--9 of FIG. 3 in a second embodiment of the test interface system 900. In this embodiment, the probe head structure 114 includes a support deflection gap 990 between the deflectable probe head 318 and the probe head support 314. It has been discovered that support deflection gap 990 provides additional flexibility for the deflectable probe head 318 while preventing permanent plastic deformation by limiting the amount of deflection or deformation of the deflectable probe head 318.

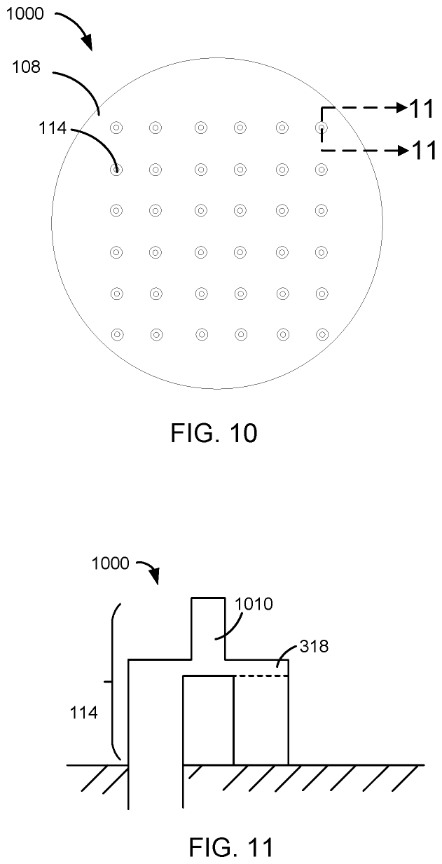

Referring now to FIG. 10, therein is shown a top view of the test interface platform 108 in a third embodiment of the test interface system 1000. The top view depicts the probe head structure 114 in a concentric structure configuration. The concentric structure configuration includes extensions protruding from the probe head structure 114.

Referring now to FIG. 11, therein is shown a cross sectional view of the test interface platform 108 of FIG. 10 along line 11--11 of FIG. 10. The cross sectional view depicts the probe head structure 114 with the protrusions as a probe pin 1010 attached to and extending from the surface of the deflectable probe head 318. The probe pin 1010 is a conductive structure for contacting test points on device under test 110 of FIG. 1. The probe pin 1010 can enable a more precise contact point with the test points for the device under teat 110 relative to the deflectable probe head 318.

The probe pin 1010 can be made from a conducive material including metals, such as elemental copper, silver, or gold, or metallic alloys, such as copper alloys, silver alloys, or gold alloys. In general the probe pin 1010 is made of a material that is similar to or the same as that of the deflectable probe head 318.

For illustrative purposes, the probe pin 1010 is shown positioned at the center of surface of the deflectable probe head 318, however, it is understood that the probe pin 1010 can be positioned differently. For example, the probe pin 1010 can be offset from the center of the surface of the deflectable probe head 318. In general, the probe pin 1010 extends perpendicularly from the surface of the

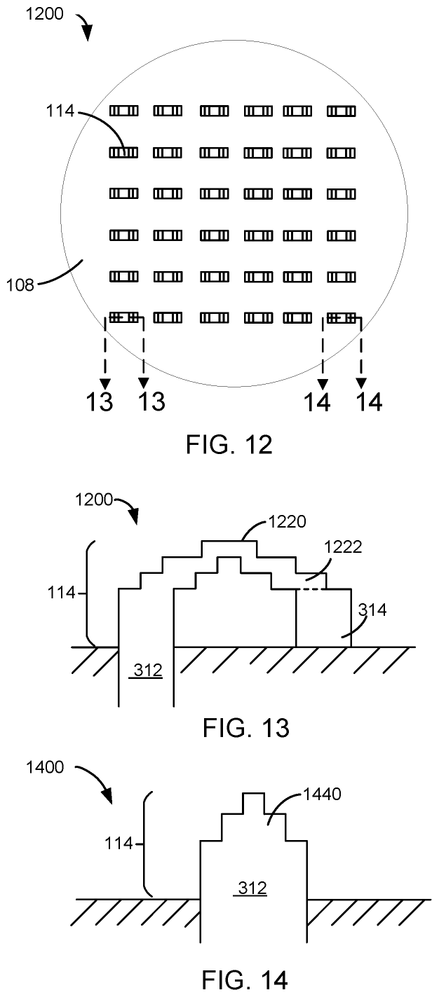

Referring now to FIG. 12, therein is shown a top view of the test interface platform 108 in a fourth embodiment of the test interface system 1200. The top view depicts the probe head structure 114 having a multi- tier configuration.

Referring now to FIG. 13, therein is shown a cross sectional view of the test interface platform 108 of FIG. 12 along line 13--13 of FIG. 12. The cross sectional view depicts the probe head structure 114 with the deflectable probe head 318 as a multi-tiered probe head 1220. The multi-tiered probe head 1220 is an offset stacked conductive structure having exposed surfaces at different levels. For example, the multi-tiered probe head 1220 can include multiple instances of contact tiers 1222 arranged in a tapered configuration such that a portion of each tier is exposed. The outer or lower instances of the contact tiers 1222 can be attached to the probe conductive connector 312 and the probe head support 314 and build up to form a stepped arch structure at a point between the probe conductive connector 312 and the probe head support 314.

To maximize structural integrity while allowing for maximum elastic deformability, the dimensions for each of the contact tiers 1222 can differ from one another. For example, the contact tiers 1222 can have a cross sectional dimension that is narrower and thicker than those above, with the uppermost instance of the contact tiers 1222 having the widest and thinnest cross sectional dimension of the contact tiers 1222 in the multi-tiered probe head 1220. For illustrative purposes, the multi-tiered probe head 1220 is shown, including three levels of the contact tiers 1222, although it is understood that the multi-tiered probe head 1220 can include a different number of the contact tiers 1222.

It has been discovered that the multi-tiered step structure 1220 provides increased surface area for contacting testing points on the device under test 110 of FIG. 1 while maintaining the capability to elastically deform.

Referring now to FIG. 14, therein is shown a cross sectional view of the test interface platform 108 of FIG. 12 along line 14--14 of FIG. 12 in a fifth embodiment of the test interface system 1400. In this embodiment, the test interface platform 108 includes the probe conductive connectors 312 in a wedge configuration 1440. The wedge configuration 1440 provides increased surface area for contact of testing points on the device under test 110 by allowing interconnect structures, such as microbumps, formed on the surface of the device under test 110 to contact the sides of the wedge configuration 1440. The probe head structure 114 that includes the probe conductive connectors 312 in the wedge configuration 1440 can be absent the deformable probe head 318 of FIG. 3 and the probe head support 314 of FIG. 3. As an example, the probe conductive connectors 312 in the wedge configuration 1440 can be formed as a multi-tiered structure through the connector formation process of FIG. 4 by reducing the width of each successive addition to the exposed portion of the probe conductive connectors 312.

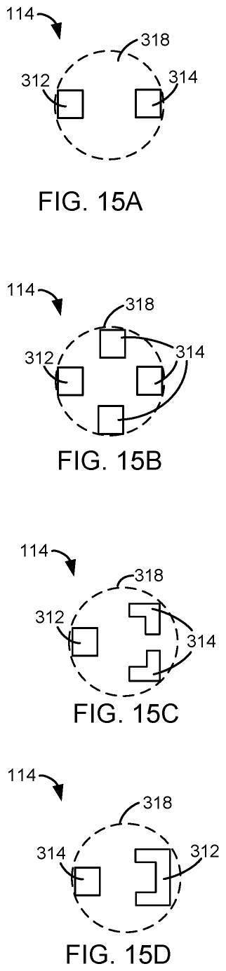

Referring now to FIGS. 15A-15D, therein are shown top views of the probe head structure 114 of FIG. 1. The top view illustrates exemplary positions and configurations of the probe conductive connector 312, the probe head support 314, or a combination thereof. In FIGS. 15A-15D, the deflectable probe head 318 is illustrated as a dashed circle to show the positions, shape, and configurations of the probe conductive connector 312 the probe head support 314 that would normally be obscured from a top view of the probe head structure.

For further illustrative purposes, the deflectable probe head 318 is shown having a circular or elliptical shape, although it is understood that the deflectable probe head 318 can have a different shape. For example, the deflectable probe head 318 can have a square or rectangular shape, a triangular shape, pentagonal shape, or any other polygonal shape.

Referring now to FIG. 15A, there in is shown the probe head structure 114 including a single instance of the probe conductive connector 314 and a single instance of the probe head support 314. The configuration of the single instance of the probe conductive connector 314 and the single instance of the probe head support 314 can provide the maximum amount of deflection of the deflectable probe head 318 since the deflectable probe head 318 is supported at only two positions.

For illustrative purposes, the probe conductive connector 314 and the probe head support 314 is shown as having a rectangular cross section, although it is understood that the probe conductive connector 314 and the probe head support 314 can have a different cross-sectional shape. For example, the probe conductive connector 314 and the probe head support 314 can have a circular cross sectional shape, a triangular cross sectional shape, or any other polygonal cross sectional shape. Further, the probe conductive connector 314 and the probe head support 314 are positioned under the deflectable probe head 318 directly across from one another, although it is understood that the probe conductive connector 314 and the probe head support 314 can be located at any position relative to one another.

Referring now to FIG. 15B, there in is shown the probe head structure 114 including a single instance of the probe conductive connector 312 and multiple instances of the probe head support 314. The multiple instances of the probe head support 314 can improve stability of the deflectable probe head 318, but can potentially reduce the degree, which the deflectable probe head 318 can deform under load.

For illustrative purposes, the probe head structure 114 is shown with three instances of the probe head support 314, although it is understood that the probe head structure 114 can include a different number of the probe head support 314. For example, the probe head structure 114 can include two, four, or more of the probe head support 314. Further, the multiple instances of the probe head support 314 is shown positioned in a diamond configuration with the probe conductive connector 312, although it is understood that the multiple instances of the probe head support 314 and the probe conductive connector 312 can be positioned differently.

Referring now to FIG. 15C, there in is shown the probe head structure 114 including a single instance of the probe conductive connector 312 and the probe head support having a cross sectional shape in an angled configuration. The angled configuration can provide increased support of the deflectable probe head 318 while reducing the contact surface area with the probe head support 314. The angled configuration can reduce the number of instances of the probe head support 314 while maximizing the degree of deflection of the deflectable probe head 318.

Referring now to FIG. 15C, there in is shown the probe head structure 114 including a single instance of the probe conductive connector 312 and the probe head support having a cross sectional shape in a bracket configuration. The bracket configuration can provide increased contact surface area for support of the deflectable probe head 318 while reducing the number of additional instances of the probe head support 314 that need to be formed.

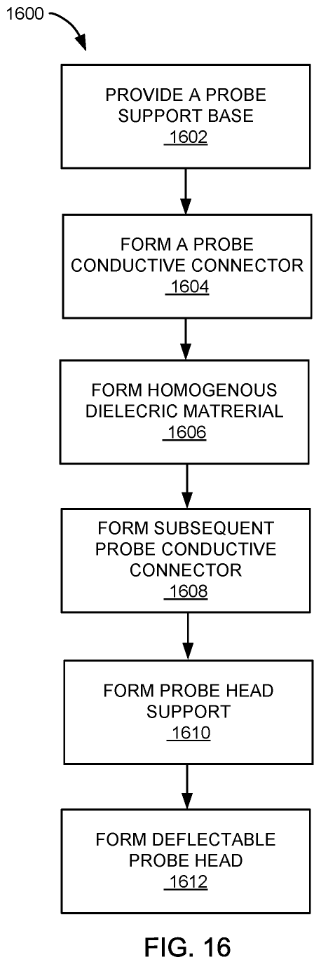

Referring now to FIG. 16, therein is shown a flow chart of a method 1600 of manufacturing of a test interface system 100 in an embodiment of the present invention. The method 1600 includes: providing a probe base in a block 1602; forming a portion of a probe conductive connector on the probe base in a block 1604; forming a homogenous dielectric structure around the portion of the probe conductive connector in a block 1606; forming a probe head structure on the homogenous dielectric structure including: forming a subsequent portion of the probe conductive connector extending away from the homogenous dielectric structure in a block 1608; forming a probe head support adjacent to the probe conductive structure and extending from the homogenous dielectric structure in a block 1610; and forming a deflectable probe head attached to the probe conductive connector and suspended over a deflection gap between the probe conductive connector probe head support in a block 1612.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A test interface system comprising:
a probe support base;
a homogenous dielectric structure formed on the probe support base;
a probe head structure formed on the homogenous dielectric structure, including:
a probe conductive connector partially embedded in and extending from the homogenous dielectric structure;
a probe head support adjacent to the probe conductive connector and extending from the homogenous dielectric structure; and
a deflectable probe head attached to the probe conductive connector and suspended over a deflection gap between the probe conductive connector probe head support.

2. The system of claim 1, wherein the deflectable probe head is a conductive sheet.

3. The system of claim 1, wherein the probe head structure includes a support deflection gap between the probe head support and the deflectable probe head.

4. The system of claim 1, wherein the deflectable probe head is a multi-tiered probe head.

5. The system of claim 1, further comprising probe pin extending from the deflectable probe head.

6. The system of claim 1, wherein the probe head support is formed from a non-conductive material.

7. The system of claim 1, wherein a portion of the probe head support is embedded in the homogenous dielectric structure.

8. The system of claim 1, wherein the probe support base is a redistribution platform.

9. The system of claim 1, wherein the probe support base is a substrate.

10. The system of claim 1, wherein the probe support base is a semiconductor wafer including a post-passivation structure formed thereon.

11. A method of manufacturing a test interface system comprising:
providing a probe support base;
forming a portion of a probe conductive connector on the probe support base;
forming a homogenous dielectric structure around the portion of the probe conductive connector;
forming a probe head structure on the homogenous dielectric structure including:
forming a subsequent portion of the probe conductive connector extending away from the homogenous dielectric structure;
forming a probe head support adjacent to the probe conductive connector and extending from the homogenous dielectric structure; and
forming a deflectable probe head attached to the probe conductive connector and suspended over a deflection gap between the probe conductive connector probe head support.

12. The method of claim 11, wherein forming the deflectable probe head includes forming the deflectable probe head as a sheet.

13. The method of claim 11, wherein forming the deflectable probe head includes forming the deflectable probe head with a support deflection gap between the probe head support and the deflectable probe head.

14. The method of claim 11, wherein forming the deflectable probe head includes forming the deflectable probe head as a multi-tiered probe head.

15. The method of claim 11, further comprising forming a probe pin extending from the deflectable probe head.

16. The method of claim 11, wherein forming the probe head support includes forming the probe head support from a non-conductive material.

17. The method of claim 11, wherein forming the probe head support includes forming the probe head support partially embedded in the homogenous dielectric structure.

18. The method of claim 11, wherein providing the probe support base includes providing the probe support base as a redistribution platform.

19. The method of claim 11, wherein providing the probe support base includes providing the probe support base as a substrate.

20. The method of claim 11, wherein providing the probe support base includes providing the probe support base as a semiconductor wafer including a post-passivation structure formed thereon.
